(19) United States
(12) Patent Application Publication
(10) Pub. No.: US 2018/0286704 A1
(43) Pub. Date: Oct. 4, 2018

(54) PROCESSES AND METHODS FOR APPLYING UNDERFILL TO SINGULATED DIE

(71) Applicant: Intel Corporation, Santa Clara, CA (US)

(72) Inventors: Elizabeth M. Nofen, Phoenix, AZ (US); Arjun Krishnan, Evanston, IL (US); James C. Matayabas, JR., Gilbert, AZ (US); Venmathy McMahan, Hillsboro, OR (US); Nisha Ananthakrishnan, Chandler, AZ (US); Yonghao Xiu, Chandler, AZ (US)

(73) Assignee: Intel Corporation, Santa Clara, CA (US)

(21) Appl. No.: 15/477,053

(22) Filed: Apr. 1, 2017

(51) Int. Cl. H01L 21/56; H01L 21/66; H01L 21/67; H01L 21/782; H01L 21/82

(52) U.S. Cl. CPC H01L 21/563; H01L 22/12; H01L 22/14; H01L 21/82; H01L 21/67005; H01L 21/782; H01L 22/20

(57) ABSTRACT

A process for applying an underfill material to a die is disclosed. A wafer is diced into a plurality of dies (without having any underfill film thereon) such that the dies have exposed bumps prior to an underfill process. Thus, the dies can be tested about their bump-sides because the bumps are entirely exposed for testing. The dies are then reconstituted bump-side up on a carrier panel in an array such that the dies are separated from each other by a gap. Underfill material (e.g., epoxy flux film) is then vacuum laminated to the carrier panel and the plurality of dies to encapsulate the dies. The underfill material is then cut between adjacent dies such that a portion of the underfill material covers at least one side edge of each die. The encapsulated dies are then removed from the carrier panel, thereby being prepared for a thermal bonding process to a substrate. Associated devices are provided.

### TECHNICAL FIELD

Embodiments described herein relate generally to processes and methods for applying underfill material to singulated die.

### BACKGROUND

Wafer-level underfill processes are particularly useful in certain chip attach applications to enable a tight keep out zone and for fine pitch architectures. Such wafer-level underfill processes involve lamination of a b-staged epoxy film over solder bumps on a solder bump-side of the wafer prior to singulating the wafer into dies. After dicing the wafer, the singulated dies have an underfill film covering the solder bump-side, but not the side edges. Because the perimeter portions of the solder bump-side are devoid of (or lack sufficient) underfill film, voids may exist upon thermally bonding the die to a substrate. Also, once the dies have been laminated with an underfill material while in wafer form, the copper bumps are no longer accessible for certain processes, such as for testing purposes. Therefore such procedures are usually performed at the wafer-level prior to deposition of the underfill material.

### BRIEF DESCRIPTION OF THE DRAWINGS

Invention features and advantages will be apparent from the detailed description which follows, taken in conjunction with the accompanying drawings, which together illustrate, by way of example, various invention embodiments; and, wherein:

FIG. 1A illustrates a schematic side plan view of a process for making a laminated die;

FIG. 1B illustrates a schematic side plan view of the laminated die of FIG. 1A;

FIG. 2A illustrates a schematic side plan view of a die in accordance with an example embodiment;

FIG. 2B illustrates a schematic bottom plan view of the die of FIG. 2A in accordance with an example embodiment;

FIG. 2C illustrates a schematic side plan view of the die of FIG. 2A flipped and attached to a substrate in accordance with an example embodiment;

FIG. 3 illustrate a process of making a die in accordance with an example embodiment;

FIG. 4 illustrates a process of attaching the die of FIGS. 2A and 3 to a substrate in accordance with an example embodiment;

FIG. 5 illustrates a process of attaching the die of FIGS. 2A and 3 to a substrate in accordance with an example embodiment;

FIG. 6 illustrates a process for manufacturing an electronics package device in accordance with an example embodiment;

FIG. 7 illustrates a process for manufacturing an electronics package device in accordance with an example embodiment; and

FIG. 8 illustrates a plan view of a system in accordance with an example embodiment.

### DESCRIPTION OF EMBODIMENTS

Before invention embodiments are disclosed and described, it is to be understood that no limitation to the particular structures, process steps, or materials disclosed herein is intended, but also includes equivalents thereof as would be recognized by those ordinarily skilled in the relevant arts. It should also be understood that terminology employed herein is used for the purpose of describing particular examples only and is not intended to be limiting. The same reference numerals in different drawings represent the same element. Numbers provided in flow charts and processes are provided for clarity in illustrating steps and operations and do not necessarily indicate a particular order or sequence. Unless defined otherwise, all technical and scientific terms used herein have the same meaning as commonly understood by one of ordinary skill in the art to which this disclosure belongs.

As used in this written description, the singular forms “a,” “an” and “the” include express support for plural referents unless the context clearly dictates otherwise. Thus, for example, reference to “a layer” includes a plurality of such layers.

In this disclosure, “comprises,” “comprising,” “containing” and “having” and the like can have the meaning ascribed to them in U.S. Patent law and can mean “includes,” “including,” and the like, and are generally interpreted to be open ended terms. The terms “consisting of” or “consists of” are closed terms, and include only the components, structures, steps, or the like specifically listed in conjunction with such terms, as well as that which is in accordance with U.S. Patent law. “Consisting essentially of” or “consists essentially of” have the meaning generally ascribed to them by U.S. Patent law. In particular, such terms are generally closed terms, with the exception of allowing inclusion of additional items, materials, components, steps, or elements, that do not materially affect the basic and novel characteristics or function of the item(s) used in connection therewith. For example, trace elements present in a composition, but not affecting the composition's nature or characteristics would be permissible if present under the “consisting essentially of” language, even though not expressly recited in a list of items following such terminology. When using an open ended term in the written description, like “comprising” or “including,” it is understood that direct support should be afforded also to “consisting essentially of” language as well as “consisting of” language as if stated explicitly and vice versa.

The terms “first,” “second,” “third,” “fourth,” and the like in the description and in the claims, if any, are used for distinguishing between similar elements and not necessarily for describing a particular sequential or chronological order. It is to be understood that the terms so used are interchangeable under appropriate circumstances such that the embodiments described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments described herein are, for example, capable of operation in other orientations than those illustrated or otherwise described herein.

The term “coupled,” as used herein, is defined as directly or indirectly connected in an electrical or nonelectrical manner. “Directly coupled” means that objects, elements, or structures are coupled in physical contact with one another. Objects described herein as being “adjacent to” each other may be in physical contact with each other, in close proximity to each other, or in the same general region or area as each other, as appropriate for the context in which the phrase is used. Occurrences of the phrase “in one embodiment,” or “in one aspect,” herein do not necessarily all refer to the same embodiment or aspect.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, sizes, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually.

This same principle applies to ranges reciting only one numerical value as a minimum or a maximum. Furthermore, such an interpretation should apply regardless of the breadth of the range or the characteristics being described.

Reference throughout this specification to “an example” means that a particular feature, structure, or characteristic described in connection with the example is included in at least one embodiment. Thus, appearances of the phrases “in an example” in various places throughout this specification are not necessarily all referring to the same embodiment.

Furthermore, the described features, structures, or characteristics may be combined in any suitable manner in one or more embodiments. In this description, numerous specific details are provided, such as examples of layouts, distances, network examples, etc. One skilled in the relevant art will recognize, however, that many variations are possible without one or more of the specific details, or with other methods, components, layouts, measurements, etc. In other instances, well-known structures, materials, or operations are not shown or described in detail but are considered well within the scope of the disclosure.

### Example Embodiments

An initial overview of technology embodiments is provided below and specific technology embodiments are then described in further detail. This initial summary is intended to aid readers in understanding the technology more quickly but is not intended to identify key or essential features of the technology nor is it intended to limit the scope of the claimed subject matter.

In one embodiment, a process for applying an underfill material to dies is disclosed. The process comprises arranging a plurality of dies bump-side up on a carrier panel in an array and depositing an underfill film to the carrier panel and to encapsulate the array. The underfill film is then cut between adjacent dies of the array to form a plurality of encapsulated singulated dies. In one example there is provided a process for making an electronics device comprising providing a die comprising an underfill film encapsulating the die and covering at least one side edge of the die, and bonding the bump-side surface to a substrate, wherein the underfill film is deposited after the die is singulated from a wafer and before the die is bonded to the substrate. In one example there is provided an unattached die comprising a bump-side and side edges, and an underfill film encapsulating the bonding side and covering at least one side edge.

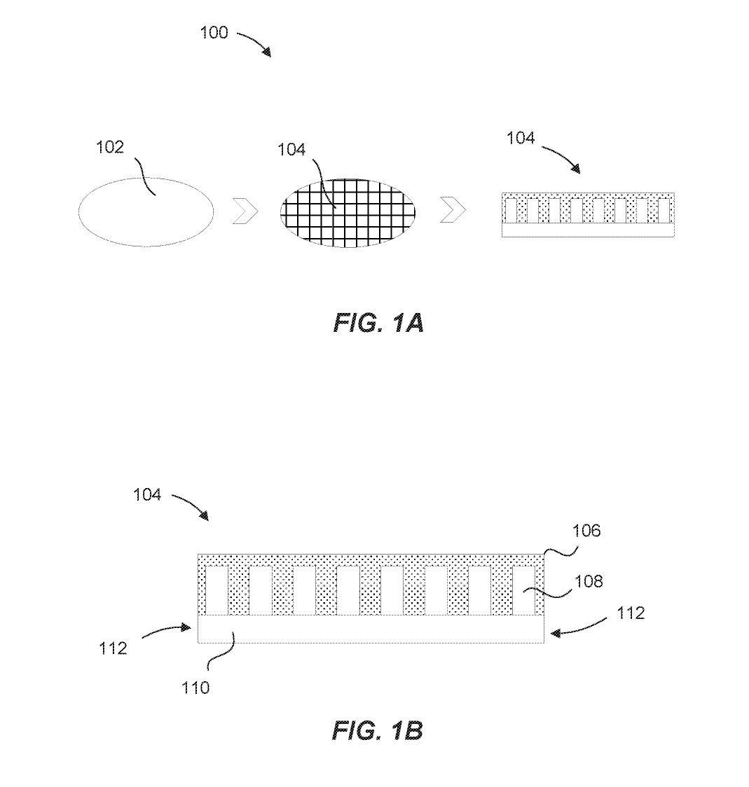

FIG. 1A illustrates a process 100 of manufacturing a die. The process 100 includes manufacturing a wafer 102 and depositing an underfill film to the wafer 102. Then, the wafer 102 is diced into singulated dies 104 that each have an underfill film 106 covering the bumps 108 of each die 104, as shown on FIG. 1B. The die 104 includes a die substrate 110 having four side edges 112 (2 side edges labeled) that are exposed, meaning that the underfill film 106 only covers the active surface or bump-side surface of the die 104. Notably, once the die 104 is singulated, the underfill film 106 prevents access to the bumps of the die 104, which may be needed for a variety of other processes (e.g., testing the bumps, etc.) before bonding the die 104 to an assembly.

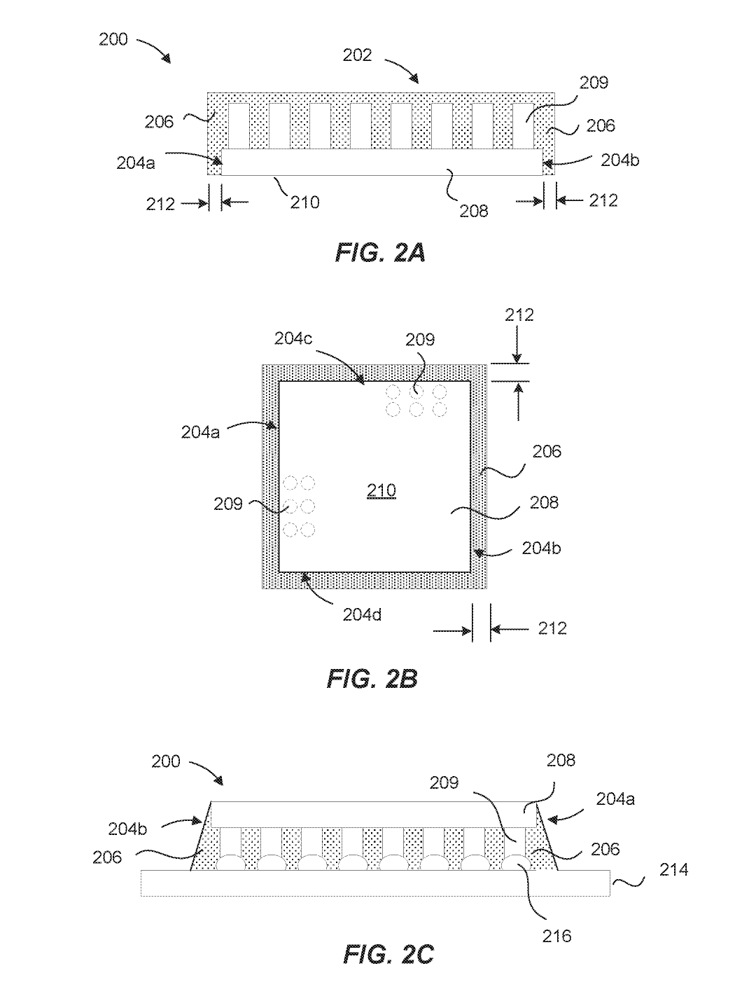

FIGS. 2A and 2B illustrate an unattached die 200 according to an example of the present disclosure. FIG. 2A shows a side elevation schematic view and FIG. 2B shows a bottom schematic view of FIG. 2A. “Unattached” refers to the fact that the die 200 is not attached to a substrate or any other component. In one example, the die 200 comprises a bump-side 202, side edges 204a-d, and an underfill film 206 encapsulating the bump-side 202 and covering at least one side edge (any one or more of side edges 204a-d). In this example, all four side edges 204a-d are covered by the underfill film 206, and the underfill film 206 encapsulates bumps 209 disposed along the bump-side 202 of the unattached die 200.

More specifically, the die 200 comprises a die substrate 208 having the four side edges 204a-d. The die substrate 208 comprises a carrier attach side 210 opposite the bump-side 202. As best illustrated on FIG. 2B, the underfill film 206 has a planar surface area that is greater than a surface area of the bump-side 202 of the die 200 (or the carrier attach side 210). Thus, the underfill film 206 laterally extends beyond the side edges 204a-d to cover or encapsulate the side edges 204a-d, as shown on FIG. 2A for side edges 204a and 204b. In other words, an underfill thickness 212 is disposed laterally beyond all four side edges 204a-d. This provides additional underfill film 206 around a perimeter of the die 200, which helps to reduce or minimize voids when the die 200 is bonded to a substrate 214. This is illustrated on FIG. 2C, showing the die 200 bonded to a substrate 214 along bumps 216 of the substrate. Such bonding can be made by a thermal bonding process, for example. Notably, the perimeter edges of the underfill film 206 (around the perimeter of the die 200) have the additional underfill film 206 that extends from the die substrate 208 down to the substrate 214 that fully encapsulates the side edges 204a-d and the bumps 209 and 214 once the die 200 is bonded. In one embodiment, the underfill film 206 can be in, or extend into, a same plane as the carrier attach side 210. This helps to reduce or minimize voids, which maximizes efficiency of the die 200 when attached and operating.

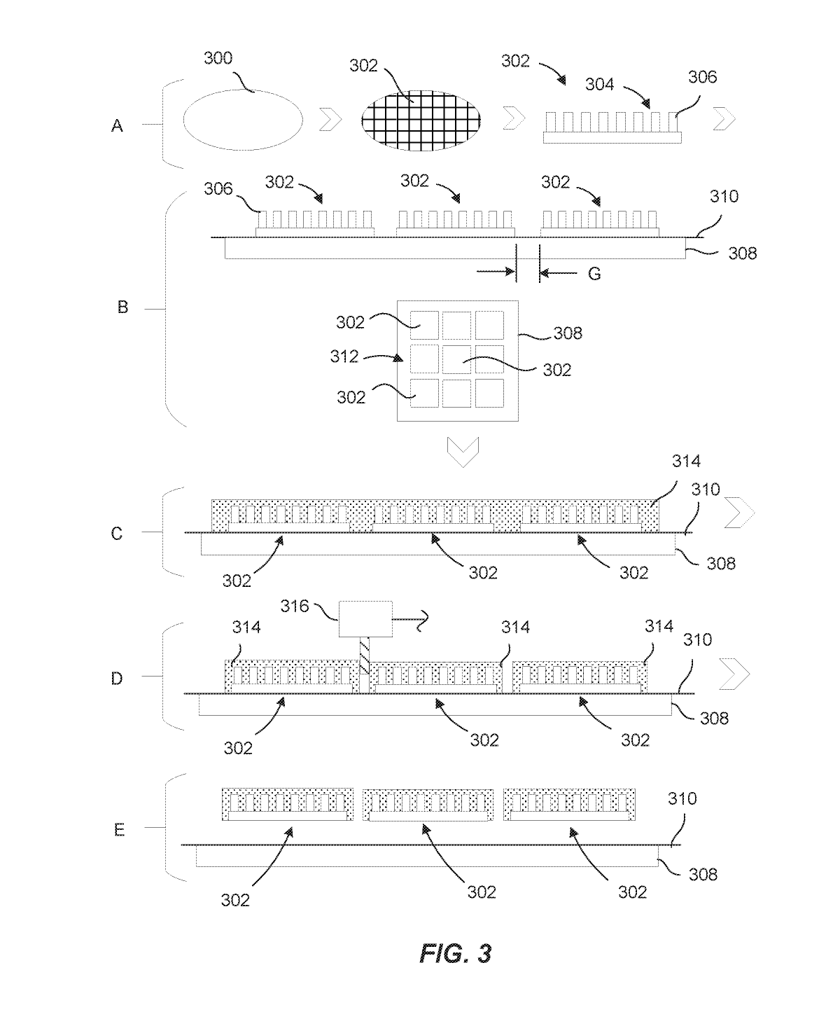

FIG. 3 illustrates a process for applying an underfill material to a plurality of unattached dies, such as the unattached die 200 of FIGS. 2A and 2B, in accordance with an example of the present disclosure. At process A, a wafer 300 is diced into a plurality of dies 302. At this point in the process, the wafer 300 and the dies 302 do not have any underfill film or other underfill material thereon. Thus, the dies 302 have a bump-side 304 having a plurality of bumps 306 that are entirely exposed, which allows for other processes to the dies 302, such as testing the bumps, for instance. Thus, in one example, each of the dies 302 are test sorted for mechanical and electrical integrity. Other processes can be implemented regarding the dies 302 when the bump-sides 304 are exposed.

Once the dies 302 are singulated from the wafer 300, at process B the dies are reconstituted on a carrier panel 308 bump-side up via a temporary adhesive 310, such as a thermal release tape with a heat release temperature of 90-120 degrees Celsius. The dies 302 are preferable reconstituted onto the panel 308 at room temperature via the temporary adhesive 310. The carrier panel 308 can be a wafer, a panel of stainless steel, glass, copper, pre-preg, etc. In one example, the dies 302 are reconstituted in an array of dies 312 and separated from each other by predefined gaps G on the carrier panel 308. The array 312 can be any number of dies arranged in any formation such that dies are adjacent each other and separated by a gap. In one example, the gaps G are distances between 0.2 mm and 0.4 mm, although other gap distances are possible. The array could instead be a single row of dies, or it can be a 2×2 array, a 5×5 array, or any combination of an array such that the dies are arranged in an array pattern (e.g., a matrix of dies linearly adjacent each other, such as shown at process B of FIG. 3).

At process C, once the dies 302 are reconstituted on the carrier panel 308 an underfill film 314 is deposited onto the carrier panel 308 and the array of dies 312 such that the underfill film 314 encases or covers the bump-sides 304 of each die 302 and the side edges of each die 302, as illustrated. The underfill film 314 is in wafer or panel form before being deposited onto the carrier panel 308. In a preferred example, the underfill film 314 is vacuum laminated, which provides a uniform laminated upper surface area (note that some of the bumps may protrude through the underfill film 314, which is typical around the perimeter bumps). In one example, the underfill film 314 is an epoxy flux film, or even a liquid or a powder. The underfill film 314 may be pre B-stage or B-staged during process C of FIG. 3. In other examples, the underfill film 314 (or material) can be applied by printing, curtain coating, molding, lamination, or other known methods. The epoxy flux film can be homopolymerized or may contain at least one hardener, such as amines, phenols, anhydrides, and the like. Other materials can be selected from acrylates, bismaleimides, polyesters, polyimides, polyolefins, polystyrene, polyurethanes, and the like, and combinations thereof. The underfill material typically comprises filler materials for mechanical property enhancement. Examples of fillers include silica, alumina, boron nitride, zinc oxide and like and their mixtures. The filler materials often are used in a multitude of average particle sizes and a wide variety of particle sizes can be used. The underfill of the present discloser may contain additives known in the art, including colorants, catalysts, inhibitors, ion trappers, stress absorbers, polymers, surfactants, binding agents, fluxing agents, and the like, and combinations thereof.

At process D, a cutting tool 316 cuts only through the underfill film 314 between adjacent dies 302 about the predefined gaps G, thereby forming a plurality of encapsulated singulated dies (as shown at process E). The cutting tool 316 can be any existing tool for cutting dies or encapsulate or underfill film materials. In one example, the tool 316 has a saw blade that is approximately 0.025 mm to 0.25 mm, such as many standard blades, diamond blades, and resin blades. Thus, in one example where the gaps G are 0.2 mm, and the saw blade is 0.025 mm, an additional underfill film material 212 (FIG. 2A) will have a thickness of approximately 0.0875 mm disposed laterally around the side edges of each die 302, as shown and discussed further regarding FIGS. 2A and 2B.

At process E, once the encapsulated dies 302 are separated from each other by the tool 316, the encapsulated singulated dies 302 can be removed from the carrier panel 308 and be prepared for a bonding process. The dies 302 can be removed by heating the carrier panel 308 to a temperature corresponding to the temperature characteristic of the temporary adhesive 310 (e.g., a heat release tape). The temporary adhesive 310 should have a release temperature below the cure onset temperature but above the lamination temperature of the underfill film, such as between 90-120 degrees Celsius are preferable. In an alternative example, the temporary adhesive comprises ultraviolet tape and the carrier panel comprises ultraviolet-transparent glass. Thus, the plurality of dies can be removed by utilizing an ultraviolet light source directed through the gaps to separate adjacent dies from each other by using radiation waves to cut the underfill film.

The processes of FIG. 3 can be applied to a single die (instead of an array), however various drawbacks may exist, such as voids during pick-and-place of the underfill film for a single die, non-uniformity of the underfill material post application, and such as de-taping complexities post lamination. Thus, an array of dies is preferable because vacuum lamination can be incorporated along an array of dies.

Laminating the underfill film 314 to an array of dies (as opposed to a single die) allows for better, more uniform underfill coverage along the bumps of each die, including more uniformity in thickness immediately above the bumps as well as at the die edges. It also provides high TPT processes for MCP packages, and a scalable process for small dies, large dies, memory chips, PCH, etc. The process of FIG. 3 also allows leveraging wafer reconstitution fan out package supply chain/learning. Other advantages and reasons for applying die level underfill after dicing/singulation include increased flexibility of testing the die, common die pull, use of shuttle wafers, and use of external silicon die post die preparation.

The processes of FIG. 3, and the devices disclosed herein for dies, also pertain to microelectronic packages, which can utilize the processes of FIG. 3. Microelectronic packages comprising die or dies prepared with the processes of FIG. 3 would be of value for assembly of low cost packages with high reliability performance and tight keep out zones of the underfill material.

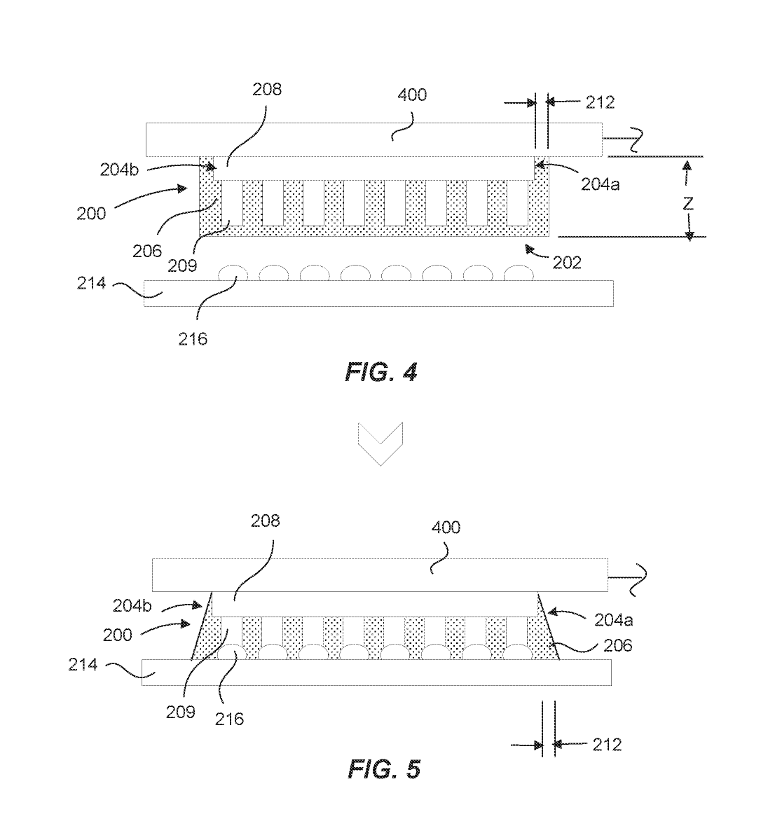

FIGS. 4 and 5 show one such bonding process being a thermal bonding process that bonds the die 200 to the substrate 214 (e.g., see FIG. 2C). Specifically, the die 200 can be formed via the processes described regarding FIG. 3. Here, the die 200 is flipped and coupled to a thermal compression bonding device 400. Notably, the underfill film 206 vertically extends a predefined distance from an active side (bump-side) surface 202 of the die 200 to define a selected gap height Z of the underfill film 206. Thus, when vacuum laminating the underfill film 206, a thickness of the film can be pre-selected in order to control or define such selected gap height Z. This assists to control gap height, which is important when bonding the die 302 to the substrate 214 to ensure proper contact between the die 302 and the substrate 400. As shown on FIG. 5, the thermal compression bonding device 400 can thermally bond the die 200 to the substrate 214 along bumps 216 bonded to bumps 209.

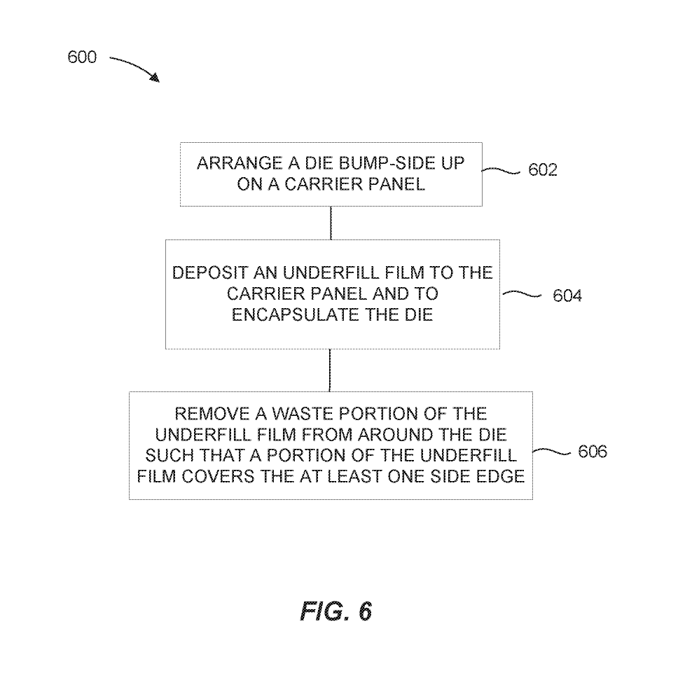

FIG. 6 illustrates a process 600 for applying an underfill material to a die(s) (whether to a single die, or an array of dies). At operation 602, the process comprises arranging a die bump-side up on a carrier panel, such as die 302 of process B of FIG. 5. At operation 604, the process comprises depositing an underfill film (or material) to the carrier panel and to encapsulate the die, such as described regarding process C of FIG. 5. At operation 606, the process comprises removing a waste portion of the underfill film from around the die (e.g., cutting around the die) such that a portion of the underfill film covers the at least one side edge, such as described regarding FIGS. 2A-3 (particularly process D of FIG. 3).

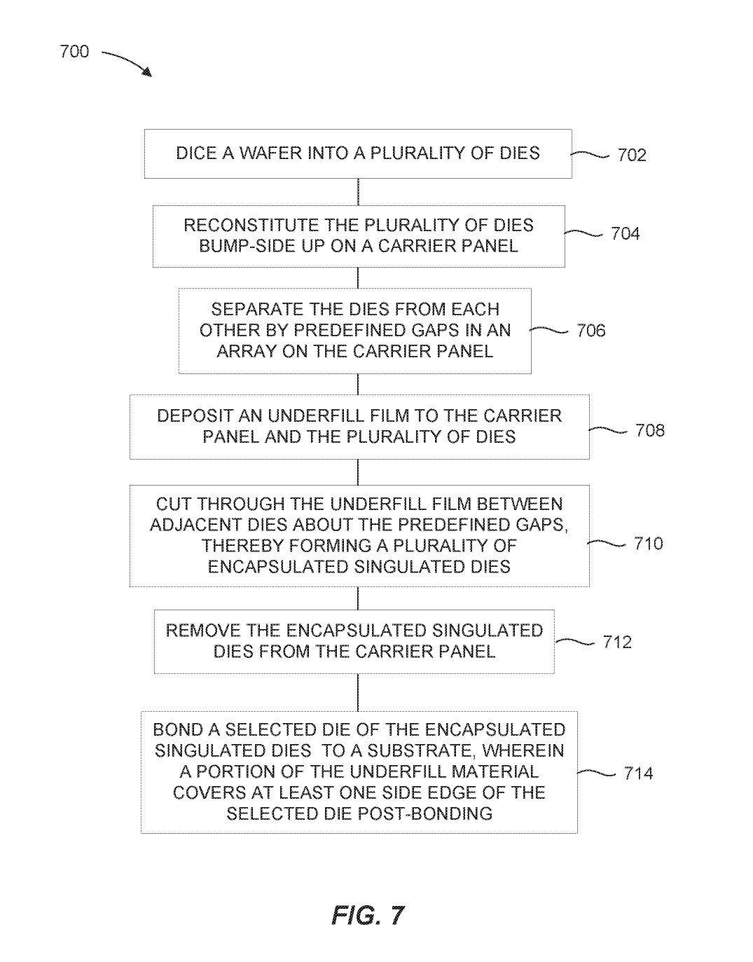

FIG. 7 illustrates a process 700 for a process for applying an underfill material to a plurality of unattached dies. At operation 702, the process comprises dicing a wafer into a plurality of dies (e.g., process A of FIG. 3). At operation 704, the process comprises reconstituting the plurality of dies bump-side up on a carrier panel (e.g., process B of FIG. 3). At operation 706, the process comprises depositing an underfill film to the carrier panel and the plurality of dies (e.g., process C of FIG. 3). At operation 708, the process comprises separating the dies from each other by predefined gaps in an array on the carrier panel (e.g., process B of FIG. 3). At operation 710, the process comprises cutting through the underfill film between adjacent dies about the predefined gaps, thereby forming a plurality of encapsulated singulated dies (e.g., process D of FIG. 3). At operation 712, the process comprises removing the encapsulated singulated dies from the carrier panel (e.g., process E of FIG. 3). At operation 714, the process comprises bonding a selected die of the encapsulated singulated dies to a substrate, wherein a portion of the underfill material covers at least one side edge of the selected die post-bonding, as further described herein.

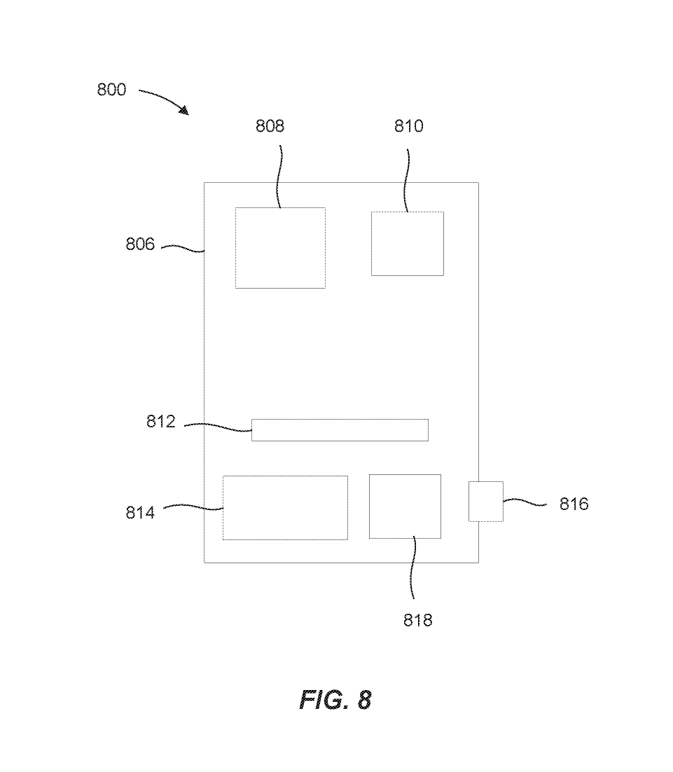

FIG. 8 illustrates an example computing system 800. The computing system 800 can include a package device 808 having an encapsulated singulated die (e.g., 200, 302) as disclosed herein, coupled to a motherboard 806. In one aspect, the computing system 800 can also include a processor 810, a memory device 812, a radio 818, a heat sink 814, a port 816, a slot, or any other suitable device or component, which can be operably coupled to the motherboard 806. The computing system 800 can comprise any type of computing system, such as a desktop computer, a laptop computer, a tablet computer, a smartphone, a server, etc. Other embodiments need not include all of the features specified in FIG. 8, and may include alternative features not specified in FIG. 8.

### Examples

The following examples pertain to further embodiments.

In one example there is provided a process for applying an underfill material to at least one die. The process comprises arranging a die bump-side up on a carrier panel and depositing an underfill film to the carrier panel and to encapsulate the die.

In one example, the process comprises maintaining a portion of the underfill film from around at least one side edge of the die.

In one example, the process comprises removing a waste portion of the underfill film from around the die such that a portion of the underfill film covers the at least one side edge.

In one example, the process comprises removing a waste portion of the underfill film from around the die such that a portion of the underfill film covers perimeter side edges of the die.

In one example, depositing the underfill film further comprises one of laminating, printing, coating, or molding the underfill film onto the carrier panel to encapsulate the die.

In one example, arranging the die further comprises temporarily adhering the die to the carrier panel with a release tape.

In one example, depositing the underfill film further comprises selectively defining a thickness of the underfill film to a predefined distance above an active side of the die.

In one example, the process comprises singulating the die from a wafer prior to arranging the die on the carrier panel.

In one example, the process comprises testing the bump-side of the die after singulating the die from the wafer.

In one example, the process comprises arranging the die and a plurality of dies to form an array of dies on the carrier panel, wherein each die is separated from adjacent dies by predefined gaps.

In one example, the process comprises depositing the underfill film to the carrier panel to encapsulate the array of dies along the bump-side and side edges of each die.

In one example, the process comprises cutting through the underfill film between adjacent dies about the predefined gaps, thereby forming a plurality of encapsulated singulated dies.

In one example, the process comprises removing the encapsulated singulated dies from the carrier panel.

In one example, the underfill film of each encapsulated singulated die covers all side edges of said die.

In one example, arranging the plurality of dies further comprises temporarily adhering the dies to the carrier panel with a release tape.

In one example, depositing the underfill film further comprises selectively defining a thickness of the underfill film to a predefined distance above an active side of the die.

In one example, the process comprises singulating the dies from a wafer prior to arranging the dies on the carrier panel.

In one example, the process comprises testing the bump-side of each die after singulating the dies from the wafer.

In one example there is provided a process for making an electronics device comprising providing a die comprising an underfill film encapsulating the die and covering at least one side edge of the die, and bonding the bump-side surface to a substrate, wherein the underfill film is deposited after the die is singulated from a wafer and before the die is bonded to the substrate.

In one example, providing the die comprises dicing a wafer to form a plurality of dies including the die.

In one example, the process comprises testing the bump-side of each die after singulating the dies from the wafer and before encapsulating each die with the underfill film.

In one example, the process comprises reconstituting the dies bump-side up on a carrier panel with a temporary adhesive and in an array of reconstituted dies.

In one example, reconstituting the dies comprises separating each die respective to adjacent dies by predefined gaps between sides of adjacent dies.

In one example, the process comprises vacuum laminating an underfill film to the carrier panel and the dies to encapsulate the array, thereby covering the bump-side and side edges of each die.

In one example, the process comprises cutting through the underfill film between adjacent dies about the predefined gaps such that a portion of underfill film remains covering the side edges of each die.

In one example, the process comprises removing the array of dies from the carrier panel.

In one example, the dies are prepared for thermal compression bonding to a substrate.

In one example there is provided a process for applying an underfill material to a plurality of unattached dies. The process comprises dicing a wafer into a plurality of dies; reconstituting the plurality of dies bump-side up on a carrier panel; and depositing an underfill film to the carrier panel and the plurality of dies.

In one example, the process comprises separating the dies from each other by predefined gaps in an array on the carrier panel.

In one example, depositing the underfill film comprises encapsulating the bump-side and at least one side edge of each die.

In one example, the process comprises cutting through the underfill film between adjacent dies about the predefined gaps, thereby forming a plurality of encapsulated singulated dies.

In one example, the process comprises removing the encapsulated singulated dies from the carrier panel.

In one example, the process comprises bonding a selected die of the encapsulated singulated dies to a substrate, wherein the substrate comprises solder balls bonded to bumps of the selected die, and wherein a portion of the underfill material covers at least one side edge of the selected die post-bonding.

In one example, the process comprises testing the bump-side of each die after dicing the dies from the wafer.

In one example, the process comprises reconstituting the dies bump-side up on a carrier panel with a temporary adhesive and in an array of reconstituted dies.

In one example, the temporary adhesive comprises thermal release film.

In one example, the process comprises removing the plurality of dies by utilizing an ultraviolet light source, wherein the temporary adhesive comprises ultraviolet tape and the carrier panel comprises glass.

In one example, the process comprises adhering the plurality of dies to the carrier panel during the reconstitution process.

In one example, the process comprises depositing the underfill film further comprises vacuum laminating the underfill film to the carrier panel and the dies to encapsulate the array, thereby covering the bump-side and side edges of each die

In one example there is provided an unattached die comprising a bump-side and side edges, and an underfill film encapsulating the bonding side and covering at least one side edge.

In one example, the underfill film covers all side edges of the die.

In one example, the die comprises a die substrate having a carrier attach side opposite the bump-side, and wherein the side edges comprise four side edges defining a perimeter of the die.

In one example, the underfill film covers the four side edges of the die, and wherein a planar surface area of the underfill film is greater than a surface area of the bump-side of the die.

In one example, the underfill film covers the entire die except for the carrier attach side of the die.

In one example, the underfill film laterally extends beyond the at least one side edge to cover said side edge.

In one example, the underfill film vertically extends a predefined distance above an active side of the die to define a selected gap height of the underfill film between a top of the underfill film and the active side of the die.

In one example, the die is singulated from a wafer and is unattached from an electronics assembly.

In one example, the die is formed via a dicing process prior to singulation from the wafer.

In one example, the underfill film is one of laminated, printed, coated, or molded to the die.

In one example, the underfill film is an epoxy flux film.

In one example there is provided an electronics assembly comprising an assembly circuit board electrically coupleable to a computer system and the unattached die electrically coupled to the assembly circuit board via a bonding process.

Circuitry used in electronic components or devices (e.g., a die) of an electronic device package can include hardware, firmware, program code, executable code, computer instructions, and/or software. Electronic components and devices can include a non-transitory computer readable storage medium which can be a computer readable storage medium that does not include signal. In the case of program code execution on programmable computers, the computing devices recited herein may include a processor, a storage medium readable by the processor (including volatile and non-volatile memory and/or storage elements), at least one input device, and at least one output device. Volatile and non-volatile memory and/or storage elements may be a RAM, EPROM, flash drive, optical drive, magnetic hard drive, solid state drive, or other medium for storing electronic data. Node and wireless devices may also include a transceiver module, a counter module, a processing module, and/or a clock module or timer module. One or more programs that may implement or utilize any techniques described herein may use an application programming interface (API), reusable controls, and the like. Such programs may be implemented in a high level procedural or object oriented programming language to communicate with a computer system. However, the program(s) may be implemented in assembly or machine language, if desired. In any case, the language may be a compiled or interpreted language, and combined with hardware implementations.

While the forgoing examples are illustrative of the specific embodiments in one or more particular applications, it will be apparent to those of ordinary skill in the art that numerous modifications in form, usage and details of implementation can be made without departing from the principles and concepts articulated herein.

What is claimed is:

1. A process for applying an underfill material to at least one die, the process comprising:
arranging a die bump-side up on a carrier panel; and
depositing an underfill film to the carrier panel and to encapsulate the die.

2. The process of claim 1, further comprising maintaining a portion of the underfill film from around at least one side edge of the die.

3. The process of claim 1, further comprising removing a waste portion of the underfill film from around the die such that a portion of the underfill film covers the at least one side edge.

4. The process of claim 1, further comprising removing a waste portion of the underfill film from around the die such that a portion of the underfill film covers perimeter side edges of the die.

5. The process of claim 1, wherein depositing the underfill film further comprises one of laminating, printing, coating, or molding the underfill film onto the carrier panel to encapsulate the die.

6. The process of claim 1, wherein arranging the die further comprises temporarily adhering the die to the carrier panel with a release tape.

7. The process of claim 1, wherein depositing the underfill film further comprises selectively defining a thickness of the underfill film to a predefined distance above an active side of the die.

8. The process of claim 1, further comprising singulating the die from a wafer prior to arranging the die on the carrier panel.

9. The process of claim 8, further comprising testing the bump-side of the die after singulating the die from the wafer.

10. The process of claim 1, further comprising arranging the at least one die and a plurality of dies to form an array of dies on the carrier panel, wherein each die is separated from adjacent dies by predefined gaps.

11. The process of claim 10, further comprising vacuum laminating the underfill film to the carrier panel to encapsulate the array of dies along the bump-side and side edges of each die.

12. The process of claim 11, further comprising cutting through the underfill film between adjacent dies about the predefined gaps, thereby forming a plurality of encapsulated singulated dies.

13. The process of claim 12, further comprising removing the encapsulated singulated dies from the carrier panel.

14. The process of claim 12, wherein the underfill film of each encapsulated singulated die covers all side edges of said die.

15. The process of claim 10, wherein arranging the plurality of dies further comprises temporarily adhering the dies to the carrier panel with a release tape.

16. The process of claim 11, wherein depositing the underfill film further comprises selectively defining a thickness of the underfill film to a predefined distance above an active side of the die.

17. The process of claim 10, further comprising singulating the dies from a wafer prior to arranging the dies on the carrier panel.

18. The process of claim 10, further comprising testing the bump-side of each die after singulating the dies from the wafer.

19. An unattached die, comprising:
a die comprising a bump-side and side edges; and
an underfill film encapsulating the bump-side and covering at least one side edge.

20. The unattached die of claim 19, wherein the underfill film covers all side edges of the die.

21. The unattached die of claim 19, wherein the die comprises a die substrate having a carrier attach side opposite the bump-side, and wherein the side edges comprise four side edges defining a perimeter of the die.

22. The unattached die of claim 21, wherein the underfill film covers the four side edges of the die, and wherein a planar surface area of the underfill film is greater than a surface area of the bump-side of the die.

23. The unattached die of claim 21, wherein the underfill film covers the entire die except for the carrier attach side of the die.

24. The unattached die of claim 19, wherein the underfill film laterally extends beyond the at least one side edge to cover said side edge.

25. The unattached die of claim 19, wherein the underfill film vertically extends a predefined distance above an active side of the die to define a selected gap height of the underfill film between a top of the underfill film and the active side of the die.

26. The unattached die of claim 19, wherein the die is singulated from a wafer and is unattached from an electronics assembly.

27. The unattached die of claim 19, wherein the underfill film is one of laminated, printed, coated, or molded to the die.

28. The unattached die of claim 19, wherein the underfill film is an epoxy flux film.
